(19) United States
(12) Patent Application Publication
(10) Pub. No.: US 2022/0293877 A1
(43) Pub. Date: Sep. 15, 2022

(54) CORE-SHELL QUANTUM DOT PREPARING METHOD, CORE-SHELL QUANTUM DOT AND QUANTUM DOT ELECTROLUMINESCENT DEVICE COMPRISING THE SAME

(71) Applicant: Najing Technology Corporation Limited, Hangzhou, Zhejiang (CN)

(72) Inventors: Xiaopeng CHEN, Hangzhou, Zhejiang (CN); Haiyang ZHAO, Hangzhou, Zhejiang (CN); Yangla XIE, Hangzhou, Zhejiang (CN)

(21) Appl. No.: 17/285,493

(22) PCT Filed: Aug. 1, 2019
(86) PCT No.: PCT/CN2019/098916

§ 371 Date: Apr. 15, 2021

(30) Foreign Application Priority Data
Oct. 18, 2018 (CN) 201811216944.7

(51) Int. Cl. H01L 51/50; C09K 11/02; C09K 11/08; B82Y 20/00; B82Y 30/00; B82Y 40/00

(52) U.S. Cl. CPC H01L 51/502; C09K 11/02; C09K 11/0805; C09K 11/0811; C09K 11/0816; B82Y 20/00; B82Y 30/00; B82Y 40/00

(57) ABSTRACT

The disclosure provides a core-shell quantum dots preparing method, core-shell quantum dots and a quantum dot electroluminescent device including the core-shell quantum dots. The method includes preparing a solution containing alloy quantum dot cores, purifying the alloy quantum dot cores; heating a mixture of a cation precursor of the shell, a carboxylic acid, the alloy quantum dot cores and a solvent for a certain period of time, after it, the carboxylic acid presents in the mixture being free carboxylic acid; adding an fatty amine and an anion precursor of the shell into the mixture to coat the alloy quantum dot cores to obtain the core-shell quantum dot. The surface of the core-shell quantum dots includes a fatty amine ligand, which amounts for at least 80% of all the ligands on the surface of the core-shell quantum dots, and the core-shell quantum dots are high in luminescence efficiency and stability.

### CROSS-REFERENCE TO RELATED APPLICATIONS

This application is a national application of PCT/CN2019/098916, filed on Aug. 1, 2019. The contents of PCT/CN2019/098916 are all hereby incorporated by reference.

### BACKGROUND

Quantum dot light-emitting diode (QLED) is an emerging display technology that has been expected to replace the commercialized organic light-emitting diode (OLED) display technology. In the existing quantum dot electroluminescent device structure, the luminescence efficiency of quantum dots will decrease exponentially over the emission time. Therefore, how to improve the lifetime and working stability of QLED will be the key to solving the current bottleneck of QLED development.

According to literature report, for example, Peng Xiaogang's research group has independently designed a new device structure by introducing a certain thickness of polymethylmethacrylate (PMMA) into the electron transport layer as a transition layer to balance the transport rate of electron and hole, suppressing the decay rate of quantum dots in the device in a certain extent. The external quantum efficiency (EQE) of the red quantum dot light-emitting diode (R-QLED) built on the basis of the quantum dots of the CdSe/CdS structure is up to 20.5%, and the lifetime at 100 cd m⁻² brightness can also reach more than 100,000 hours. However, the solubility of PMMA and the similar polymers are very poor and cannot be applied to inkjet printing process to prepare QLEDs, i.e., without prospect of commercial application; in addition, Qian Lei's group reported that the green CdSe@ZnS alloy quantum dots in 2015, the T₅₀ lifetime under brightness of 100cd m ⁻² is 90,000 h. Their main solution is to increase the thickness of the ZnSe shell, thereby reducing the transport rate of electron in the quantum dots so as to improve the lifetime of QLED. However, the full width at half maximum of this quantum dot material is close to 30 nm, which largely limits its application in the display field.

### SUMMARY

The main purpose of the present disclosure is to provide a method for preparing core-shell quantum dots, core-shell quantum dots, and a quantum dot electroluminescent device, so as to solve the problems of short lifetime and low working stability of QLEDs in the prior art.

In order to achieve the above objectives, according to one aspect of the present disclosure, a method of preparing core-shell quantum dots is provided, which includes: preparing a solution containing alloy quantum dot cores, and purifying the alloy quantum dot cores; heating a mixture including a cation precursor of the shell, a carboxylic acid, the alloy quantum dot cores and a solvent for a certain period of time, after the certain period of time, the carboxylic acid presents in the mixture being free carboxylic acid; adding an fatty amine and an anion precursor of the shell to the mixture, coating the alloy quantum dot cores to obtain core-shell quantum dots, the molar ratio of the fatty amine to the free carboxylic acid being greater than 2:1; upon termination of the reaction, the surface of the core-shell quantum dots in the product system includes a fatty amine ligand, wherein the fatty amine ligand accounts for at least 80% of all ligands on the surface.

Optionally, the step of adding the fatty amine and the anion precursor of the shell to the mixture includes: first adding the fatty amine and then adding the anion precursor of the shell to the mixture, time interval of the additions of the fatty amine and the anion precursor of the shell being 30 minutes or less, more preferably the time interval is less than or equal to 10 minutes.

Optionally, preparing the solution including alloy quantum dot cores includes: preparing a solution including quantum dot cores, and alloying the quantum dot cores to obtain the solution including the alloy quantum dot cores.

Optionally, the fatty amine is selected from primary amines having a carbon chain length of 8 to 22.

Optionally, the carboxylic acid is selected from fatty acids having a carbon chain length of 8 to 22.

Optionally, the method includes: S1a, heating a mixture including a first carboxylate of group II element precursor, a first carboxylic acid and a solvent for a certain period of time, adding a first group VI element precursor for further reaction, and after the reaction is terminated, purifying to obtain II-VI quantum dot cores; S2a, heating a mixture including the first carboxylate of group II element precursor, a second carboxylate of group II element precursor, a second carboxylic acid and the solvent to a first temperature and purging with gas for a certain period of time, heating to a second temperature and adding the II-VI quantum dot cores, the fatty amine, the first group VI element precursor for reaction, after the reaction is terminated, purifying to obtain II-VI@II-II-VI quantum dots, dispersing the purified II-VI@II-II-VI quantum dots in the solvent to obtain a solution including the II-VI@II-II-VI quantum dots.

Optionally, the method includes S3a, heating the first carboxylate of group II element precursor, the second carboxylate of group II element precursor and the solution including II-VI@II-II-VI quantum dots to the first temperature and purging with gas for a certain period of time, heating to a second temperature, and adding the fatty amine, and the second group VI element precursor to obtain a solution including II-VI@II-II-VI/II-II-VI quantum dots.

Optionally, the method includes: S1b, heating a mixture including a first carboxylate of group II element precursor, a first carboxylic acid and a solvent mixture for a certain period of time, adding a first group VI element precursor for further thermal reaction, and after the reaction is terminated, purifying to obtain II-VI quantum dot cores; S2b, heating a mixture including a second carboxylate of Group II element precursor, a second carboxylic acid and the solvent to a first temperature reaction and purging with gas for a certain period of time, heating to a second temperature and adding the II-VI quantum dot cores, the fatty amine, the first group VI element precursor and the second group VI element precursor, after the reaction is terminated, purifying to obtain II-VI@II-VI-VI group quantum dots, and dispersing the purified II-VI@II-VI-VI quantum dots in the solvent.

Optionally, the method further includes S3b, adding a second carboxylate of group II element precursor, the II-VI@II-II-VI group quantum dots and the solvent and heating to a first temperature reaction and purging with gas for a certain period of time, heating to a second temperature and adding the fatty amine and the second group VI element precursor to obtain a solution including II-VI@II-VI-VI/II-VI quantum dots.

Optionally, the method includes: S1c, heating a mixture of a first carboxylate of group II element precursor, a first carboxylic acid and a solvent for a certain period of time, and adding a first group VI element precursor for further thermal reaction, and after the reaction is terminated, purifying to obtain the II-VI quantum dot cores; S2c, heating a mixture of a second carboxylate of Group II element precursor, a second carboxylic acid and the solvent to a first temperature reaction and purging with gas for a certain period of time, heating to a second temperature and adding the II-VI quantum cores, the fatty amine and the second group VI element precursor, after the reaction is terminated, purifying to obtain II-VI@II-VI quantum dots, dispersing the purified II-VI@II-VI quantum dots in the solvent.

Optionally, the method includes: S1d, heating a mixture of the second carboxylate of Group II element precursor, the first carboxylic acid and a solvent for a certain period of time, adding the first Group VI element precursor to react for a certain period of time, adding the first carboxylate of Group II element precursor and the first group VI element precursor to react for a certain period of time, and after the reaction is terminated, purifying to obtain quantum dot alloy cores; S2d, heating the mixture of the second carboxylate of Group II element precursor, a second carboxylic acid and the solvent to a first temperature reaction and purging with gas for a certain period of time, heating to a second temperature and adding the II-II-VI of quantum dot alloy cores, the fatty amines, and the second group VI element precursor, after termination of the reaction, purifying to obtain II-II-VI@II-VI quantum dots.

Optionally, the first temperature is 150 to 200° C. and the second temperature is 280 to 310° C.

Optionally, the first carboxylate of Group II element precursor is cadmium carboxylate, and the second carboxylate of Group II element precursor is zinc carboxylate; preferably the C chain length of the cadmium carboxylate and the C chain length of the zinc carboxylate are less than 8.

Optionally, the first group VI element precursor is a Se precursor, and the second group VI element precursor is a S precursor.

According to another aspect of the present application, there is provided a core-shell quantum dot for a quantum dot electroluminescent device, which includes an alloy quantum dot core and a shell layer, the surface of the core-shell quantum dot includes fatty amine ligand, and the fatty amine ligands accounts for at least 80% of all ligands.

According to another aspect of the present disclosure, there is provided a quantum dot electroluminescent device including a quantum dot light-emitting layer, and the quantum dot light-emitting layer includes core-shell quantum dots prepared by any of the above methods.

The preparation method of the present disclosure can control the amount of fatty amine ligands of the core-shell quantum dots, so that the fatty amine ligand is controlled to account for at least 80% of all ligands on the surface. The ligand of the core-shell quantum dots of the present disclosure has a relatively high proportion of fatty amine. Under electrical excitation condition, on the one hand, the ligand is electrochemically inert, it will not react with charge carriers and the carriers will not be consumed, so that most of the carriers are used for electroluminescence; on the other hand, the fatty amine ligand can be relatively inert, it will not fall off and form a large number of defects to affect the luminescence efficiency of quantum dots. As the core-shell quantum dots include fatty amine ligand, their luminescence efficiency is high, the corresponding device is stable, and of high reliability.

### BRIEF DESCRIPTION OF THE DRAWINGS

The drawings of the specification forming a part of the application are used to provide a further understanding of the application, and the exemplary embodiments and descriptions of the application are used to explain the application, and do not constitute an improper limitation of the application. In the accompanying figures:

FIG. 1 shows the infrared spectrum of oleylamine.

FIG. 2 shows the infrared spectrum of the quantum dots according to Example 1.

FIG. 3 shows the infrared spectrum of zinc oleate.

FIG. 4 shows the infrared spectrum of quantum dots according to Comparative Example 1.

FIG. 5 shows comparison of electric field stability between Example 4 and Comparative Example 4 under 100 mA cm⁻².

FIG. 6 shows ¹H-NMR spectrum of oleylamine.

FIG. 7 shows the ¹H-NMR spectrum of quantum dots of Example 1.

### DETAILED DESCRIPTION OF THE EMBODIMENTS

It should be pointed out that the following detailed descriptions are all illustrative and are intended to provide further explanations for the disclosure. Unless otherwise indicated, all technical and scientific terms used herein have the same meaning as commonly understood by those of ordinary skill in the technical field to which this disclosure belongs.

It should be noted that the terms used here are only for describing specific implementations, and are not intended to limit the exemplary implementations according to the present disclosure. As used herein, unless the context clearly indicates otherwise, the singular form is also intended to include the plural form. In addition, it should also be understood that when the terms “comprising” and/or “including” are used in this specification, they indicate there are features, steps, operations, devices, components, and/or combinations thereof. It should be noted that the terms “first” and “second” in the specification and claims of the present disclosure are used to distinguish similar objects, and are not necessarily used to describe a specific sequence. “S1a”, “S2a”, etc. refer to preparation steps.

As described in the background art, in order to solve the problems of short lifetime and low working stability of QLEDs, this disclosure proposes a method for preparing core-shell quantum dots includes: preparing a solution containing alloy quantum dot cores, and purifying the alloy quantum dot cores; heating a mixture including a cation precursor of the shell, a carboxylic acid, the alloy quantum dot cores and a solvent for a certain period of time, after the certain period of time, the carboxylic acid presents in the mixture being free carboxylic acid (part of the carboxylic acid is reacted, and the rest is free carboxylic acid); adding an fatty amine and an anion precursor of the shell to the mixture, coating the alloy quantum dot cores to obtain core-shell quantum dots, the molar ratio of the fatty amine to the free carboxylic acid being greater than 2:1; upon termination of the reaction, the surface of the core-shell quantum dots in the product system includes a fatty amine ligand, wherein the fatty amine ligand accounts for at least 80% of all ligands on the surface.

Since the free carboxylic acid and the fatty amine will react to form amide, the molar ratio of fatty amine to free carboxylic acid being greater than 2:1, if the cation precursor being a divalent cation, the amount of the free carboxylic acid being approximately the amount of carboxylic acid material (mole) minus 2 times of the amount of the cation (mole), a large amount of fatty amine ensures sufficient raw material as fatty amine ligand, so the above method can ensure that the synthetic amine ligand accounts for at least 80% of the core-shell quantum of all ligands on the surface. Compared with the method of synthesizing core-shell quantum dots and then performing ligand exchange, the above preparation method is relatively simple.

The core-shell quantum dots of the present disclosure have fatty amine ligand (electrochemically inert ligand) on the outer surface of the quantum dots. Under electrical excitation condition, on the one hand, because the ligand is electrochemically inert, it will not react with carriers and the carriers will not be consumed, so that most of the carriers are used for emission; on the other hand, because the electrochemically inert ligand is relatively stable, it will not fall off and form a large amount of defects which affect the luminescence efficiency of quantum dots. Therefore, the core-shell quantum dots including electrochemically inert ligand have high luminescence efficiency, and the corresponding QLED devices can be relatively stable and have high reliability.

In some embodiments, the step of adding the fatty amine and the anion precursor of the shell to the mixture including: first adding the fatty amine and then adding the anion precursor of the shell to the mixture, time interval of the additions of the fatty amine and the anion precursor of the shell being 30 minutes or less, more preferably the time interval is less than or equal to 10 minutes. The addition time interval can be controlled so that the carboxylic acid will not be completely reacted (such as the reaction of carboxylic acid and fatty amine to form amide) after the anion precursor of the shell is added, and the free carboxylic acid presenting in the reaction system can interact with the anion of shell to form a precursor with higher reactivity, so as to better control over the shell growth, so that the quantum dots can maintain good monodispersity during the growth process, and obtain core-shell quantum dots with high efficiency, narrow full width at half maximum, and single exponential decay. The above method can further ensure the synthesis of core-shell quantum dots whose fatty amine ligand accounts for at least 80% of all ligands on the surface.

In other embodiments, the anion precursor of the shell is selected at least one from trioctyl phosphine selenium, tributyl phosphine selenium, octadecene-selenium, selenium powder-octadecene suspension, bis(trimethylsilyl) selenium, trioctylphosphine sulfur, tributylphosphine sulfur, octadecene-sulfur, alkanethiol, and bis(trimethylsilyl)sulfur.

In some embodiments, after terminating the reaction, purifying the core-shell quantum dots in the product system and re-dispersing them in a solvent to reduce the influence of certain substances in the product system on the quantum dots with fatty amine ligand.

In some embodiments, preparing a solution containing alloy quantum dot cores includes: preparing a solution containing quantum dot cores, and alloying the quantum dot cores to obtain a solution containing alloy quantum dot cores. The method for alloying quantum dot cores can be any method in the prior art.

In some embodiments, the alloy quantum dot core is a III-V quantum dot, which can be selected from GaNP, GaNAS, GaNSb, GaPAs, GaPSb, GaPSb, AlNAs, AlNSb, AlPAs, AlPSb, InNP, InNAs, InNSb, InPAs, InPSb or GaAlNP; the core of group III-V quantum dot may be quaternary compound and selected from GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or their combinations.

In some embodiments, the alloy quantum dot core is a II-VI group compound, which can be selected from CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, HgZnTeS, CdZnSeS, CdZnSeTe, CdZnSTe, CdHgSeS, CdHgSeTe, CdHgSTe, HgZnSeS, HgZnSeTe, or HgZnSTe.

In some embodiments, the fatty amine is selected from primary amines having a carbon chain length of 8 to 22. Compared with secondary amines and tertiary amines, primary amines have stronger coordination capabilities and can form more stable coordination bonds with the surface of quantum dots. On the other hand, compared to traditional carboxylic acid ligand or carboxylate ligand, the quantum dots with the primary amine as ligand are not prone to in-situ redox reaction under the working environment of the device, which can significantly improve the stability of the quantum dots in the electric field.

In some embodiments, the carboxylic acid is selected from saturated fatty acids or unsaturated fatty acids having a carbon chain length of 8-22. Such as lauric acid, myristic acid, stearic acid and oleic acid. Due to positive correlation between the reactivity of the carboxylic acid and the length of the carbon chain, the reactivity of the carboxylic acid in the system can be adjusted by selecting the appropriate carbon chain length, to ensure that the carboxylic acid effectively synthesize a single component shell, instead of rapidly condensing with the corresponding fatty amine to form amide, during the certain period of reaction time.

In some embodiments, the molar ratio of fatty amine to carboxylic acid is less than or equal to 20:1. The raw material can be saved and the purpose of the present disclosure can be achieved at the same time.

In some embodiments, the fatty amine ligand accounts for equal to or greater than 90% of all ligands on the surface.

As the type of alloy quantum dot cores varies, the preparation of core-shell quantum dots can be divided into various preparation methods.

In some embodiments, the method for preparing a solution containing alloy quantum dot cores includes: preparing a solution containing quantum dot cores, and alloying the quantum dot cores, and adding fatty amine during the alloying process to obtain a solution including alloying quantum dots core, the surface of the alloy quantum dot core including amine ligand. The method for preparing the solution containing alloy quantum dot cores can be any method in prior art.

In other embodiments, the method for preparing a solution containing alloy quantum dot cores includes: preparing a solution containing quantum dot cores, and alloying the quantum dot cores. That is, no fatty amine is added during the alloying process.

In some embodiments, preparing a solution containing alloy quantum dot cores includes: S1a, heating a mixture of the first carboxylate of group II element precursor, a first carboxylic acid and a solvent for a certain period of time, and adding a first group VI element precursor for further reaction. After the reaction is terminated, purifying to obtain II-VI group quantum dot cores; S2a, heating a mixture of the first carboxylate of group II element precursor, a second carboxylate of group II element precursor, a second carboxylic acid and the solvent to a first temperature and purging with gas for a certain period of time, heating to a second temperature and adding the II-VI quantum dot cores, the fatty amine, and the first VI element precursor for reaction. After the reaction is terminated, purifying to obtain II-VI@II-II- Group VI element quantum dots, and dispersing the purified II-VI@II-II-VI group quantum dots in the solvent to obtain a solution including the II-VI@II-II-VI group quantum dots.

In some embodiments, the method for preparing core-shell quantum dots further includes S3a, heating the first carboxylate of group II element precursor, the second carboxylate of group II element precursor and the solution including II-VI@II-II-VI quantum dots to the first temperature and purging with gas for a certain period of time, heating to a second temperature, and adding the fatty amine, the second group VI element precursor to obtain a solution including II-VI @II-II-VI/II-II-VI quantum dots. Through multi-shell coating, more stable quantum dots can be obtained.

In some embodiments, preparing a solution containing alloy quantum dot cores includes: S1b, heating a mixture including a first carboxylate of group II element precursor, a first carboxylic acid and a solvent mixture for a certain period of time, adding a first group VI element precursor for further thermal reaction, and after the reaction is terminated, purifying to obtain the II-VI quantum dot cores; S2b, heating a mixture including a second carboxylate of Group II element precursor, a second carboxylic acid and the solvent to a first temperature reaction and purging with gas for a certain period of time, heating to a second temperature and adding the II-VI quantum dot cores, the fatty amine, the first group VI element precursor and the second group VI element precursor, after the reaction is terminated, purifying to obtain the II-VI@II-VI-VI group quantum dots, and dispersing the purified II-VI@II-VI-VI quantum dots in the solvent.

In some embodiments, the method for preparing core-shell quantum dots further includes S3b, adding a second carboxylate of group II element precursor, the II-VI@-II-II-VI group quantum dots and the solvent and heating to a first temperature reaction and purging with gas for a certain period of time, heating to a second temperature and adding the fatty amine and the second group VI element precursor to obtain a solution including II-VI@II-VI-VI/II-VI quantum dots. Through multi-shell coating, more stable quantum dots can be obtained.

In some embodiments, the method for preparing core-shell quantum dots includes: S1c, heating a mixture of a first carboxylate of group II element precursor, a first carboxylic acid and a solvent for a certain period of time, and adding a first group VI element precursor for further thermal reaction, and after the reaction is terminated, purifying to obtain the II-VI quantum dot cores; S2c, heating a mixture of a second carboxylate of Group II element precursor, a second carboxylic acid and the solvent to a first temperature reaction and purging with gas for a certain period of time, heating to a second temperature and adding the II-VI quantum cores, the fatty amine and the second group VI element precursor, after the reaction is terminated, purifying to obtain II-VI@II-VI quantum dots, dispersing the purified II-VI@II-VI quantum dots in the solvent.

In some embodiments, it includes: S1d, heating a mixture of the second carboxylate of Group II element precursor, the first carboxylic acid and a solvent for a certain period of time, adding the first Group VI element precursor to react for a certain period of time, adding the first carboxylate of Group II element precursor and the first group VI element precursor to react for a certain period of time, and after the reaction is terminated, purifying to obtain quantum dot alloy cores; S2d, heating the mixture of the second carboxylate of Group II element precursor, a second carboxylic acid and the solvent to a first temperature reaction and purging with gas for a certain period of time, heating to a second temperature and adding the II-II-VI of quantum dot alloy cores, the fatty amines, and the second group VI element precursor, after termination of the reaction, purifying to obtain II-II-VI@II-VI quantum dots.

In some embodiments, the first temperature is 150 to 200° C., and the second temperature is 280 to 310° C.

In some embodiments, the first carboxylate of Group II element precursor is cadmium carboxylate, and the second carboxylate of Group II element precursor is zinc carboxylate; preferably the C chain length of the cadmium carboxylate and the C chain length of the zinc carboxylate are less than 8.

In some embodiments, the first group VI element precursor is a Se precursor, and the second group VI element precursor is a S precursor.

In S2, the molar ratio of the fatty amine to the second carboxylic acid is 2-20.

In other embodiments, the first carboxylic acid and the second carboxylic acid are independently selected from fatty acids with a carbon chain length of 8-22.

In other embodiments, the solvents in S1a, S1b, S1c, S1d, S2a, S2b, S2c, S2d and S3b may be the same or different, and preferably the solvent is octadecene.

In other embodiments, the carbon chain length in the first and second carboxylate group II element precursor is selected to be 8 or less.

In other embodiments, the first group VI element precursor is selected from trioctyl phosphine selenium, tributyl phosphine selenium, octadecene-selenium, selenium powder-octadecene suspension, tris(trimethylsilyl) selenium, or their combinations.

In other embodiments, the second group VI element precursor is selected from trioctyl phosphine sulfide, tributyl phosphine sulfide, octadecene-sulfur, alkanethiol, and tris(trimethylsilyl)sulfide, or their combinations.

According to another aspect of the present disclosure, a core-shell quantum dot for a quantum dot electroluminescent device includes an alloy quantum dot core and a shell, the surface of the core-shell quantum dot includes a fatty amine ligand, the fatty amine ligand accounts for equal to or greater than 80% of all ligands. Thereby achieving high electroluminescence efficiency and lifetime.

In some embodiments, the electroluminescence efficiency of the core-shell quantum dot is ≥80%, and the full width at half maximum is ≤25 nm.

According to another aspect of the present disclosure, a quantum dot electroluminescent device includes a quantum dot light-emitting layer, and the quantum dot light-emitting layer includes core-shell quantum dots prepared by any of the above methods. Thereby achieving high electroluminescence efficiency and lifetime.

### EXAMPLES

### Preparation of 0.2 M Cadmium Oleate (CdOA₂) Precursor

Cleaned a 100 mL single-neck flask with 5 mL×3 times of n-hexane, dried the flask by using a drier to ensure no liquid drops left; put a clean magnet into the flask; 2.66 g of cadmium acetate (CdAc₂.2H₂O) (10 mmol), 6.84 g of oleic Acid (OA) (24 mmol), 33.88 g of octadecene (ODE) were loaded into the flask and purged with nitrogen at 170° C. for 1 h to remove the acetic acid in the system, then cooled to room temperature and stored for later use.

### Preparation of 0.2M S-ODE

20 mmol S (0.64 g), 100 mL ODE were loaded into a 250 mL single-necked flask, and purged with nitrogen for 10-15 min; the solution was heated at 180° C. and stirred until the S powder was completely dissolved, then cooled to room temperature and stored for later use.

### Synthesis of CdSe Core

0.533 g of CdAc₂.2H₂O (2 mmol), 2.28 g of oleic acid (OA) (8 mmol), 12 g of octadecene (ODE) were loaded into a 100 mL three-necked flask, purged with nitrogen at 170° C. , and the stirring speed is 60 rpm. 0.5 M Se-suspension (Se-ODE) was prepared by dispersing 79 mg of Se powder (1 mmol) in ODE (2 mL) by sonication for 2 min. 1 mL of Se-ODE was swiftly injected into the system when the temperature was increased to 250° C., and the reaction was maintained at 240° C. under nitrogen atmosphere. The reaction was monitored by UV-Vis absorption spectrophotometer. The first exciton peak of UV was 508 nm after reacted for 15 min. Each dose of 0.1 mL of 0.5 M Se-ODE was added dropwise. After one dose of the Se-ODE was added, the reaction solution was allowed to react for 10 min. Aliquots were taken for UV-Vis measurement to monitor the reaction after 5min since the addition of one dose of Se-ODE. When the desired first exciton peak of UV was reached, the reaction was stopped. In this way, CdSe core with the first exciton peak between 510-580 nm can be synthesized and used to synthesize the quantum dots having the emission wavelength of 500-630 nm. The prepared CdSe cores were poured into a separating funnel, 20 mL of n-hexane and 70 mL of methanol were added. After mixing, the methanol layer at the bottom was discarded, this procedure was repeated for 2-3 times with methanol washing until the volume of the upper layer solution was 10-15 mL; the solution containing CdSe cores was transferred to a centrifuge tube, added with 30-40 mL of acetone, and the tube centrifuged at 4900 rpm for 3 min, discarded the liquid, and the precipitate was dissolved with ODE and centrifuged at 4900 rpm for 3 min, then the ODE solution with CdSe was measured of optical density (OD) under the first exciton peak and stored for later use.

### Synthesis of CdZnSe Core

0.367 g of ZnAc₂ (2 mmol), 2.28 g of oleic acid (OA)(8 mmol), and 12 g of octadecene (ODE) were loaded into a 100 mL three-necked flask, and purged with nitrogen, the system temperature was at 170° C., and the stirring speed was 60 rpm.

0.5 M Se-suspension (Se-ODE) was prepared by dispersing 159 mg of Se powder (2 mmol) in ODE (4 mL) by sonication for 2 min. 2 mL of Se-ODE was swiftly injected into the system when the temperature was increased to 300° C., and the reaction was maintained at 290° C. under nitrogen atmosphere. The reaction was monitored by UV-Vis absorption spectrophotometer. After 2 min reaction, 0.5 mL of 0.2 M CdOA₂ was injected, and reacted for another 10 min; then each dose of 0.1 mL of 0.5 M Se-ODE was added dropwise. After one dose of the Se-ODE was added, the reaction solution was allowed to react for 10 min. Aliquots were taken for UV-Vis measurement to monitor the reaction after 5 min since the addition of one dose of Se-ODE. When the desired first exciton peak of UV was reached, the reaction was stopped. In this way, by adjusting the amount of CdOA₂ and the addition frequency of Se-ODE, the CdZnSe core with the first exciton peak between 470-510 nm could be synthesized and was used to synthesize quantum dots with the emission wavelength of 460-500 nm. The prepared CdZnSe cores were poured into a separating funnel, were added with 20 mL of n-hexane, and 70 mL of methanol. After mixing, the methanol layer at the bottom was removed, this procedure was repeated for 2-3 times with methanol washing until the volume of upper layer solution was 10-15 mL; the solution containing CdZnSe cores was transferred to a centrifuge tube, 30-40 mL of acetone was added, and the tube was centrifuged at 4900 rpm for 3 min, the liquid phase was discarded, and the precipitate was dissolved with ODE and centrifuged at 4900 rpm for 3 min, then the ODE solution with CdZnSe was measured of OD under the first exciton peak and stored for later use.

### Example 1: Synthesis of 630 nm CdSe@CdZnSe/CdZnS QDs with RNH₂ Ligand

(1) Synthesis of CdSe@CdZnSe:

1) 26.6 mg of CdAc₂.2H ₂O (0.1 mmol), 0.183 g of ZnAc₂ (1 mmol), 1.12 g of oleic acid (OA) (4 mmol), ODE were loaded into a 100 mL three-necked flask, and purged with nitrogen at 160° C. for at least 0.5 h to remove air and acetate, and the stirring speed by magnet was 60 rpm.

2) Se-TOP solution was prepared by adding Se powder (0.25 mmol) to 0.5 mL TOP and being dissolved by sonication

3) The CdSe quantum dot cores (its UV first exciton peak=580 nm, OD=50, 25 nmol) were injected into the system in three-necked flask when the temperature was increased to 305° C. under nitrogen atmosphere.

4) 1.69 g (6 mmol) of oleylamine (OAm) was injected, then the Se-TOP solution prepared in step 2 was injected into the three-necked flask within 1 min, reacted for 20 min, aliquots were taken for PL measurement to monitor the reaction at intervals of 5 min. The CdSe@CdZnSe alloy cores with PL peak at 625 nm and full width at half maxima (FWHM) of 20 nm were finally obtained.

5) The heat source was removed to cool the system to below 100° C., a product system containing CdSe@CdZnSe was obtained.

6) Purification: the crude CdSe@CdZnSe product was moved to a 50 mL centrifuge tube, 30 mL of acetone was added to completely precipitate the QDs, then the tube was centrifuged at 4900 rpm for 3 min, the liquid phase was discarded, and the QDs were dissolved with ODE, CdSe@CdZnSe ODE solution was obtained.

7) Centrifuged the ODE solution containing CdSe@CdZnSe at 4900 rpm for 3 minutes, and the top layer of ODE solution was reserved for later use.

(2) Synthesis of CdSe@CdZnSe/CdZnS:

1) CdAc₂.2H ₂O (26.6 mg, 0.1 mmol), ZnAc₂ (0.183 g, 1 mmol), oleic acid (OA, 1.12 g, 4 mmol), ODE were loaded into a 100 mL three-necked flask, and purged with nitrogen at 160° C. for at least 0.5 h to remove air and acetate, and the stirring speed by magnet was 60 rpm.

2) S-TBP was prepared by adding 32 mg of S powder (1 mmol) to 2 mL TBP and being dissolved by sonication.

3) The synthesized CdSe@CdZnSe alloy cores were injected into the system when the temperature was increased to 305° C. under nitrogen atmosphere.

4) 1.69 g (6 mmol) of oleylamine (OAm) was injected, then the S-TBP solution prepared in step 2 was injected into the system within 1 min, reacted for 20 min, aliquots were taken for PL measurement to monitor the reaction at intervals of 5 min. The CdSe@CdZnSe/CdZnS-OAm QDs with PL peak at 630 nm, FWHM of 20 nm and QY of 96.3% were obtained.

5) The heat source was removed tocool the system to below 100° C.

6) Purification: the crude CdSe@CdZnSe/CdZnS-OAm product was moved to a 50 mL centrifuge tube, 30 mL of acetone was added to completely precipitate the QDs; then the tube was centrifuged at 4900 rpm for 3min, the liquid phase was discarded, and the precipitated and dired QDs were dissolved with toluene to obtain CdSe@CdZnSe/CdZnS-OAm product.

7) The toluene solution containing alloyed CdSe@CdZnSe/CdZnS-OAm was centrifuged at 4900 rpm for 3 minutes, and the top layer of toluene solution was reserved, and measured of the OD value at 450 nm in UV-Vis spectrum, and stored for later use.

### Example 2: Synthesis of 470 nm CdZnSe/ZnS QDs with RNH₂ Ligand

1) 0.183 g of ZnAc₂ (1 mmol), 1.12 g of OA (4 mmol), 5 g ODE were loaded into a 100 mL three-necked flask, and purged with nitrogen at 160° C. for at least 0.5 h to remove air and acetate, and the stirring speed by magnet was 60 rpm.

2) 2.82 g of OAm (10 mmol) and CdZnSe core (UV=478 nm, OD=50, 25 nmol) were injected into the system under nitrogen atmosphere.

3) When the temperature was increased to 300° C., 0.2 M S-ODE was added dropwise at a rate of 30 mL/h, and the reaction was terminated after 20 minutes. Aliquots were taken for PL measurement to monitor the reaction at intervals of 5 min. The CdZnSe/ZnS-OAm QDs with PL peak at 470 nm, FWHM of 20 nm and QY of 97.1% were obtained.

4) The heat source was removed to cool the system to below 100° C.

5) Purification: the crude CdZnSe/ZnS-OAm product was moved to a 50 mL centrifuge tube, 30 mL of acetone was added to completely precipitate the QDs; then the tube was centrifuged at 4900 rpm for 3 min, the liquid phase was discarded, and the precipitated and died QDs were dissolved with toluene to obtain CdZnSe/ZnS product.

6) The toluene solution containing alloyed CdZnSe/ZnS-OAm QDs was centrifuged at 4900 rpm for 3 minutes, and the top layer of toluene solution was reserved, measured of the OD value at the 395 nm in UV-Vis spectrum, and stored for later use.

### Example 3 Synthesis of 520 nm CdSe@ZnSeS/ZnS QDs with RNH₂ Ligand

(1) Synthesis of CdSe@ZnSeS

1) 0.183 g of ZnAc₂ (1 mmol), 1.12 g of OA (4 mmol), 5 g of ODE were loaded into a 100 mL three-necked flask, and purged with nitrogen at 160° C. for at least 0.5 h to remove air and acetate, and the stirring speed by magnet was 60 rpm.

2) Se-TOP was prepared by adding 20 mg of Se powder (0.4 mmol) to 0.8 mL of TOP, and being dissolved by sonication; S-TBP was prepared by adding 8 mg of S powder (0.1 mmol) to 0.2 mL of TBP, and being dissolved by sonication, then mixed the Se-TOP and S-TBP as the anion precursors for later use.

3) 2.26 g of OAm (8 mmol) and the purified CdSe core (UV=525 nm, OD=50, 25 nmol) were injected into the system under nitrogen atmosphere, then the temperature of system was increased to 305° C. within 5 min.

4) The anion precursors prepared in step 2 was injected into the system, reacted for 20 min, aliquots were taken for PL measurement to monitor the reaction at intervals of 5 min. The CdSe@ZnSeS alloy cores with PL peak at 523 nm and FWHM of 21 nm were obtained.

5) The heat source was removed to cool the system to below 100° C.

6) The crude CdSe@ZnSeS product was moved to a 50 mL centrifuge tube, 30 mL of acetone was added to completely precipitate the QDs, then the tube was centrifuged at 4900 rpm for 3 min, the liquid phase was discarded, and the precipitated and dried QDs were dissolved with ODE, CdSe@ZnSeS solution was obtained.

7) The ODE solution containing CdSe@ZnSeS was centrifuged at 4900 rpm for 3 minutes, and the top layer of ODE solution was reserved for later use.

(2) Synthesis of CdSe@ZnSeS/ZnS-OAm QDs

1) ZnAc₂ (0.183 g, 1 mmol), OA (1.12 g, 4 mmol), 5 g of ODE were loaded into a 100 mL three-necked flask, and purged with nitrogen at 160° C. for at least 0.5 h to remove air and acetate, and the stirring speed by magnet was 60 rpm.

2) OAm (2.26 g, 8 mmol) and the CdSe@ZnSeS (purified) solution were injected into the system under nitrogen atmosphere.

3) When the temperature was increased to 300° C., 0.2 M S-ODE was added dropwise at a rate of 30 mL/h, and the reaction was terminated after 20 minutes of addition. Aliquots were taken for PL measurement to monitor the reaction at intervals of 5 min. The CdSe@ZnSeS/ZnS-OAm QDs with PL peak at 520 nm, FWHM of 20 nm and QY of 93.8% were obtained.

4) The heat source was removed to cool the system to below 100° C.

5) Purification: the crude CdSe@ZnSeS/ZnS-OAm product was moved to a 50 mL centrifuge tube, 30 mL of acetone was added to completely precipitate the QDs; then the tube was centrifuged at 4900 rpm for 3 min, the liquid phase was discarded, and the precipitated and dried QDs were dissolved with toluene, toluene solution containing CdSe@ZnSeS/ZnS -OAm was obtained.

6) The toluene solution containing alloyed CdSe@ZnSeS/ZnS-OAm was centrifuged at 4900 rpm for 3 minutes, and the top layer of toluene solution was reserved, measured of the OD value at the 450 nm in UV-Vis spectrum, and stored for later use.

### Example 4: QLED Based on 630 nm CdSe@CdZnSe/CdZnS-OAm QDs

According to the literature (X.Dai, et al., Solution-processed, high-performance light-emitting diodes based on quantum dots, Nature 515, 96(2014).doi: 10.1038/nature13829), the 630 nm CdSe@CdZnSe/CdZnSe-OAm that prepared in Example 1 was used to prepare QLED devices. The whole process was carried out in air atmosphere. The specific procedures were as follows: PEDOT:PSS solution (BaytronPVPA1 4083, filtered through a 0.45 mm N66 filter) was spin-coated onto the ITO-coated glass substrate at 4000 rpm for 1 min, and baked at 140° C. for 10 min. Each layer within 45 s, the PVK chlorobenzene solution, 630 nm CdSe@CdZnSe/CdZnS-OAm QDs and the ethanol solution of ZnMgO nanoparticles, were spin-coated layer by layer at 2000 rpm. Finally, 100 nm Ag electrode was deposited using thermal evaporation system and the devices were encapsulated using ultraviolet-curable resin. The thickness of the CdSe@CdZnSe/CdZnS-OAm QDs layer was about 30 nm. The average external quantum efficiency (EQE) of multiple device samples could reach 18%, and the half-lifetime (T₅₀) at 100 cd m⁻² was 800,000-900,000 hours.

### Example 5: QLED Based on 470 nm CdZnSe/ZnS -OAm QDs

Differed from Example 4 in that the CdZnSe/ZnS-OAm QDs prepared in Example 2 were used. For the QLED based on 470 nm CdZnSe/ZnS-OAm QDs and prepared under air atmosphere , the average external quantum efficiency (EQE) of multiple device samples could reach 15%, and T₅₀ at 100 cd m⁻² was 9,000 -10,000 hours.

### Example 6: QLED Based on 520 nm CdSe@ZnSeS/ZnS-OAm QDs

Differed from Example 4 in that the CdSe@ZnSeS/ZnS QDs prepared in Example 3 were used. For QLED based on 520 nm CdSe@ZnSeS/ZnS -OAm QDs, the average external quantum efficiency (EQE) of multiple device samples could reach around 17%, and T₅₀ at 100 cd m⁻² was 150,000-160,000 hours.

### Comparative Example 1: Synthesis of 630 nm CdSe@CdZnSe/CdZnS-OA QDs

Differed from Example 1 in that no OAm was added in the step (4) of the preparation process of CdSe@CdZnSe and CdSe@CdZnSe/CdZnS, the other conditions were the same. The CdSe@CdZnSe/CdZnS-OA QDs with PL peak at 629 nm, FWHM of 20 nm and QY of 92.7% were obtained.

### Comparative Example 2: Synthesis of 470 nm CdZnSe/ZnS-OA QDs

Differed from Example 2 in that no OAm was added in the step (2) of the preparation process, and the other conditions were the same. The CdZnSe/ZnS-OA QDs with PL peak at 470 nm, FWHM of 20 nm and QY of 93.6% were obtained.

### Comparative Example 3: Synthesis of 520 nm CdSe@ZnSeS/ZnS-OA

Differed from Example 3 in that no OAm was added in the step (2) of the preparation process, and the other conditions were the same. The CdSe@ZnSeS/ZnS-OA QDs with PL peak at 520 nm, FWHM of 21 nm and QY of 91.9% were obtained.

### Comparative Example 4: QLED based on 630 nm CdSe@CdZnSe/CdZnS-OA QDs

Differed from Example 4 in that 630 nm CdSe@CdZnSe/CdZnS-OA QDs prepared in Comparative Example 1 were used as QDs. The average external quantum efficiency (EQE) of the multiple device samples was about 15%, and T₅₀ at 100 cd m⁻² was 120,000˜130,000 h.

### Comparative Example 5: QLED Based on 470 nm CdZnSe/ZnS-OA QDs

Differed from Example 4 in that 470 nm CdZnSe/ZnS -OA QDs prepared in Comparative Example 2 were used as QDs. The average external quantum efficiency (EQE) of the multiple device samples was about 5%, and T₅₀ at 100 cd m⁻² was <100 h.

### Comparative Example 6 QLED Based on 520 nm CdSe@ZnSeS/ZnS-OA QDs

Differed from Example 4 in that 520 nm CdSe@ZnSeS/ZnS-OA QDs prepared in Comparative Example 3 were used as QDs. The average external quantum efficiency (EQE) of the multiple device samples was about 13%, T₅₀ at 100cd m⁻² was 60,000˜70,000 h.

Characterizations of Devices:

The absorption spectra of the quantum dots were measured using a Shimadzu UV3600 spectrophotometer. Current density-voltage characterization of QLED was measured using Keithley2400. The brightness of the quantum dot light-emitting devices was measured combining a fiber integration sphere (FOIS-1) coupled with a QE-65000 Spectrometer. The external quantum efficiency of the QLED was calculated based on the current density and brightness of the device. The external quantum efficiency represents a ratio between the number of photons emitted by the light-emitting device and the number of electrons injected into the device in the observation direction, which is an important parameter to characterize the luminescence efficiency of light-emitting devices. The higher external quantum efficiency, the higher luminescence efficiency of the device. The half-lifetime of the devices were measured using the 32-channel lifetime test system customized by Guangzhou New Vision Company. The test system architecture was driving the QLED with a constant voltage or constant current source, to test the voltage or current changes; the photodiode detector and test system were used to test the brightness (photocurrent) changes of the QLED; the brightness meter was used to test and calibrate the brightness (photocurrent) of the QLED. The test results were listed in Table 1.

TABLE 1

| | EQE % | T₅₀ Lifetime/hour |
|---|---|---|
| Example 4 | ~18 | 800,000~900,000 |
| Comparative Example 4 | ~15 | 120,000~130,000 |
| Example 5 | ~15 | 9,000~10,000 |
| Comparative Example 5 | ~5 | <100 |
| Example 6 | ~17 | 150,000~160,000 |
| Comparative Example 6 | ~13 | 60,000~70,000 |

From Table 1, we can find that all examples are better than comparative examples in T₅₀ lifetime, T₅₀ in each example compared with corresponding comparative example is significantly improved, and the EQE is also improved.

The IR spectra of zinc oleate, oleylamine, CdSe@CdZnSe/CdZnS-OAm QDs of

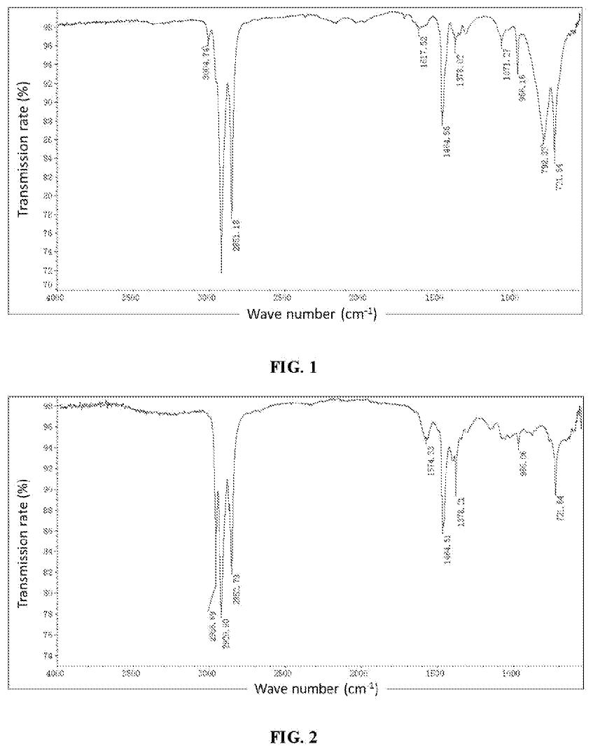

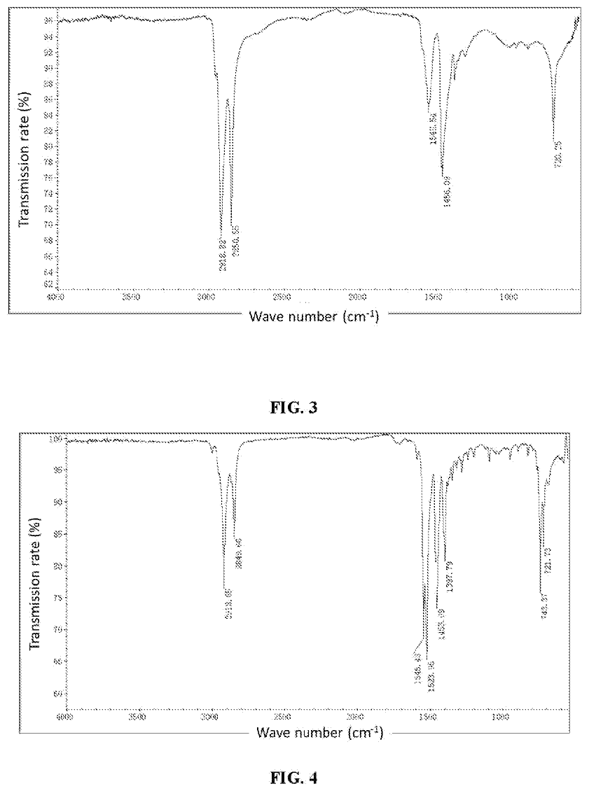

Example 1, and CdSe@CdZnSe/CdZnS-OA QDs of comparative Example 1 are respectively listed as FIG. 1-4. Compared the a sprectra of zinc oleate (FIG. 3) and CdSe@CdZnSe/CdZnS-OA QDs of comparative Example 1 (FIG. 4), we can observe that the stretching vibration peak of C═O of metal carboxylate is around 1550 cm⁻¹, and the corresponding characteristic absorption peak over quantum dots surface is almost overlapped with thatof zinc oleate and oleic acid, it means that the main ligands around the surface of CdSe@CdZnSe/CdZnS which was synthesized under carboxylic acid condition are zinc oleate and oleic acid. Then, compared the IR sprectra of oleylamine (FIG. 1) and CdSe@CdZnSe/CdZnS-OA QDs from Example 1 (FIG. 2), from the characteristic absorption peak of oleyamine, it reveals that the stretching vibration peak of N—H in oleylamine is at 1610 cm⁻¹, and moves to 1570 cm⁻¹, and the intensity of the N—H stretching vibration at 3300-3400 cm⁻¹ has a significant increase. Compared the IR sprectra of zinc oleate (FIG. 3) and QDs of Example 1 (FIG. 2), we can't find any obvious C═O stretching vibration peak in the IR spectrum of QDs which were synthesized under OAm condition in Example 1. Therefore, ligands around the surface of the quantum dots prepared in Example 1 are mainly OAm.

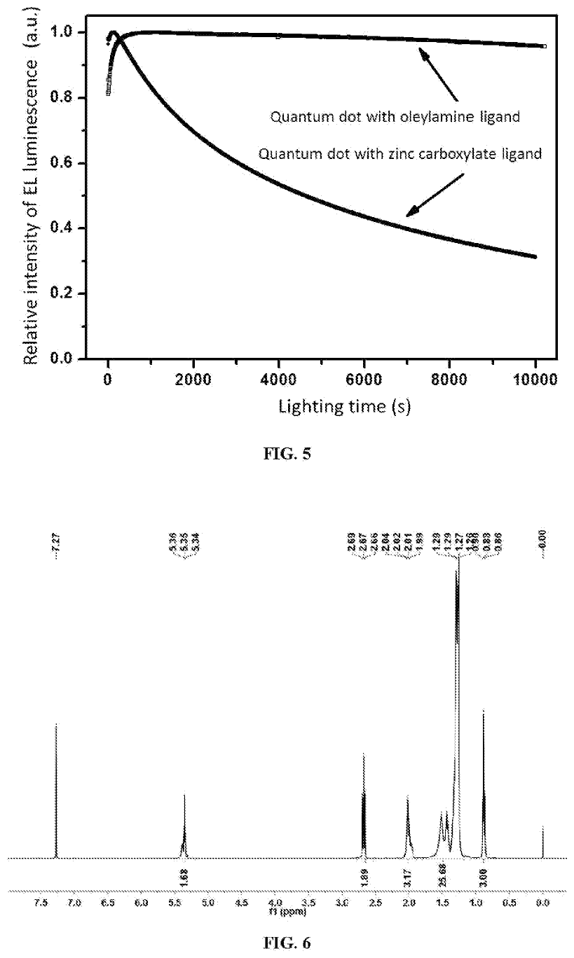

FIG. 5 shows the relative electric field stability of QLED of Example 4 and comparative Example 4. We note that the degradation rate of Example 4 is much slower than that of comparative Example 4 when the two devices were both exposed under 100 mA cm⁻² current intensity for continuous emitting, the stability performance is obviously different.

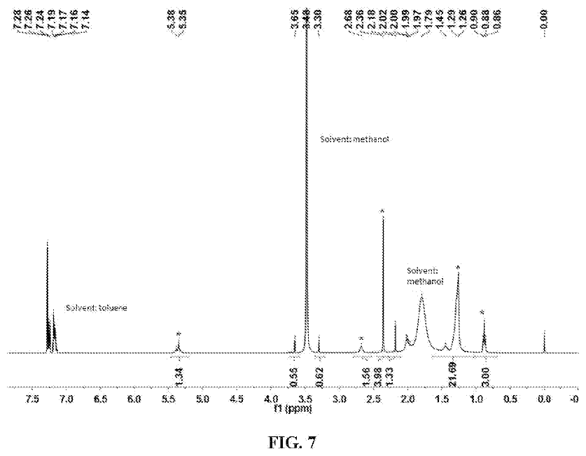

FIG. 6 is the ¹H-NMR spectrum of OAm: 1H-NMR (500 MHz, CDCl₃) 80.86 (t, 3H), 1.26-1.60 (m, 25H), 2.01 (m, 3H), 2.67 (m, 2H), 5.35 (m, 2H), i.e., there are five kinds of nuclear magnetic peaks. The NMR spectrum listed in FIG. 7, the corresponding ¹H peaks of the OAm ligand are marked as asterisk, while the unmarked peaks belong to impurities, and there is no characteristic peak of carboxylate. By calculating the integration area, we can get the ratio of oleylamine (OAm): (1.34+1.56+3.98+21.69+3)/(1.34+0.55+0.62+1.56+3 98+1.33+21.69+3)×100%=92.66%. That means, the OAm ligand of QDs in Example 1 accounted for 92.66% of all the ligands of the quantum dots.

From all of the above description, it can be concluded that the above-mentioned examples of the present disclosure achieve the following technical effects:

1). The preparation method can control the amount of the core-shell quantum dot fatty amine ligand so that the fatty amine ligand accounts for at least 80% of all ligands on the surface. Compared with the preparation method with ligand exchange, the preparation method of this disclosure is simple and reliable.

2). The outer surface of the core-shell quantum dots of the present disclosure has electrochemically inert ligands. Under electrical excitation condition, on the one hand, because the ligands are electrochemically inert, they will not react with charge carriers, i.e., without consuming carriers, so that most of the carriers are used for light emission; on the other hand, because the electrochemically inert ligand is relatively stable, it will not fall off and form a large number of defects which affects the stability of quantum dots. Therefore, the core-shell quantum dots including electrochemically inert ligands have high luminescence efficiency, the corresponding device is stable and of high reliability.

3). Since the QLED device of the present disclosure includes the aforementioned core-shell quantum dots, its performance is relatively stable and its reliability is relatively high.

The foregoing descriptions are merely demonstrative embodiments of the application, and are not used to limit the claim scope. For those skilled in the art, the application can have various modifications and changes. Any modification, equivalent replacement, improvement, etc., made within the spirit and principle of this application shall be included in the protection scope of this application.

What is claimed is:

1. A method for preparing core-shell quantum dots, wherein, comprises:
preparing a solution comprising alloy quantum dot cores, purifying the alloy quantum dot cores;
heating a mixture comprising a cation precursor of the shell, a carboxylic acid, the alloy quantum dot cores and a solvent for a certain period of time, after the certain period of time, the carboxylic acid presents in the mixture being free carboxylic acid; adding an fatty amine and an anion precursor of the shell to the mixture, coating the alloy quantum dot cores to obtain core-shell quantum dots, the molar ratio of the fatty amine to the free carboxylic acid being greater than 2:1; upon termination of the reaction, the surface of the core-shell quantum dots in the product system comprises a fatty amine ligand, wherein the fatty amine ligand accounts for at least 80% of all ligands on the surface.

2. The method for preparing core-shell quantum dots according to claim 1, wherein the step of adding the fatty amine and the anion precursor of the shell to the mixture comprises:
first adding the fatty amine and then adding the anion precursor of the shell to the mixture, time interval of the additions of the fatty amine and the anion precursor of the shell being 30 minutes or less, more preferably the time interval is less than or equal to 10 minutes.

3. The method for preparing core-shell quantum dots according to claim 1, wherein, preparing the solution comprising alloy quantum dot cores comprises:
preparing a solution comprising quantum dot cores, and alloying the quantum dot cores to obtain the solution comprising the alloy quantum dot cores.

4. The method for preparing core-shell quantum dots according to claim 1, wherein the fatty amine is selected from primary amines having a carbon chain length of 8 to 22.

5. The method for preparing core-shell quantum dots according to claim 1, wherein the carboxylic acid is selected from fatty acids having a carbon chain length of 8 to 22.

6. The method for preparing core-shell quantum dots according to claim 3, comprises:
S1a, heating a mixture comprising a first carboxylate of group II element precursor, a first carboxylic acid and a solvent for a certain period of time, adding a first group VI element precursor for further reaction, and after the reaction is terminated, purifying to obtain II-VI quantum dot cores;
S2a, heating a mixture comprising the first carboxylate of group II element precursor, a second carboxylate of group II element precursor, a second carboxylic acid and the solvent to a first temperature and purging with gas for a certain period of time, heating to a second temperature and adding the II-VI quantum dot cores, the fatty amine, the first group VI element precursor for reaction, after the reaction is terminated, purifying to obtain II-VI@II-II-VI quantum dots, dispersing the purified II-VI@II-II-VI quantum dots in the solvent to obtain a solution comprising the II-VI@II-II-VI quantum dots.

7. The method for preparing core-shell quantum dots according to claim 6, further comprising S3a, heating the first carboxylate of group II element precursor, the second carboxylate of group II element precursor and the solution comprising II-VI@II-II-VI quantum dots to the first temperature and purging with gas for a certain period of time, heating to a second temperature, and adding the fatty amine, and the second group VI element precursor to obtain a solution comprising II-VI@II-II-VI/II-II-VI quantum dots.

8. The method for preparing core-shell quantum dots according to claim 3, comprises:
S1b, heating a mixture comprising a first carboxylate of group II element precursor, a first carboxylic acid and a solvent mixture for a certain period of time, adding a first group VI element precursor for further thermal reaction, and after the reaction is terminated, purifying to obtain II-VI quantum dot cores;
S2b, heating a mixture comprising a second carboxylate of Group II element precursor, a second carboxylic acid and the solvent to a first temperature reaction and purging with gas for a certain period of time, heating to a second temperature and adding the II-VI quantum dot cores, the fatty amine, the first group VI element precursor and the second group VI element precursor, after the reaction is terminated, purifying to obtain II-VI@II-VI-VI group quantum dots, and dispersing the purified II-VI @II-VI-VI quantum dots in the solvent.

9. The method for preparing core-shell quantum dots according to claim 8, further comprising S3b, adding a second carboxylate of group II element precursor, the II-VI@II-II-VI group quantum dots and the solvent and heating to a first temperature reaction and purging with gas for a certain period of time, heating to a second temperature and adding the fatty amine and the second group VI element precursor to obtain a solution comprising II-VI@II-VI-VI/II-VI quantum dots.

10. The method for preparing core-shell quantum dots according to claim 3, comprising:
S1c, heating a mixture of a first carboxylate of group II element precursor, a first carboxylic acid and a solvent for a certain period of time, and adding a first group VI element precursor for further thermal reaction, and after the reaction is terminated, purifying to obtain the II-VI quantum dot cores;
S2c, heating a mixture of a second carboxylate of Group II element precursor, a second carboxylic acid and the solvent to a first temperature reaction and purging with gas for a certain period of time, heating to a second temperature and adding the II-VI quantum cores, the fatty amine and the second group VI element precursor, after the reaction is terminated, purifying to obtain II-VI@II-VI quantum dots, dispersing the purified II-VI@II-VI quantum dots in the solvent.

11. The method for preparing core-shell quantum dots according to claim 1, comprises:
S1d, heating a mixture of the second carboxylate of Group II element precursor, the first carboxylic acid and a solvent for a certain period of time, adding the first Group VI element precursor to react for a certain period of time, adding the first carboxylate of Group II element precursor and the first group VI element precursor to react for a certain period of time, and after the reaction is terminated, purifying to obtain II-II-VI quantum dot alloy cores;
S2d, heating the mixture of the second carboxylate of Group II element precursor, a second carboxylic acid and the solvent to a first temperature reaction and purging with gas for a certain period of time, heating to a second temperature and adding the II-II-VI of quantum dot alloy cores, the fatty amines, and the second group VI element precursor, after termination of the reaction, purifying to obtain II-II-VI@II-VI quantum dots.

12. The method for preparing a core-shell quantum dot according to claim 6, wherein the first temperature is 150 to 200° C. and the second temperature is 280 to 310° C.

13. The method for preparing a core-shell quantum dot according to claim 6, wherein the first carboxylate of Group II element precursor is cadmium carboxylate, and the second carboxylate of Group II element is zinc carboxylate;
preferably the C chain length of the cadmium carboxylate and the C chain length of the zinc carboxylate are less than 8.

14. The method for preparing a core-shell quantum dot according to claim 6, wherein the first group VI element precursor is a Se precursor, and the second group VI element precursor is a S precursor.

15. A core-shell quantum dot for a quantum dot electroluminescent device, comprising an alloy quantum dot core and a shell, wherein the surface of the core-shell quantum dot comprises a fatty amine ligand, the fatty amine ligand accounts for at least 80% of all ligands.

16. A quantum dot electroluminescent device, comprising a quantum dot emitting layer, wherein the quantum dot emitting layer comprises the core-shell quantum dots prepared by the method for preparing core-shell quantum dots according to claim 1.

17. The quantum dot electroluminescent device according to claim 16, wherein the step of adding the fatty amine and the anion precursor of the shell to the mixture comprises:
first adding the fatty amine and then adding the anion precursor of the shell to the mixture, time interval of the additions of the fatty amine and the anion precursor of the shell being 30 minutes or less, more preferably the time interval is less than or equal to 10 minutes.

18. The quantum dot electroluminescent device according to claim 16, wherein preparing the solution comprising alloy quantum dot cores comprises:
preparing a solution comprising quantum dot cores, and alloying the quantum dot cores to obtain the solution comprising the alloy quantum dot cores.

19. The quantum dot electroluminescent device according to claim 16, wherein the fatty amine is selected from primary amines having a carbon chain length of 8 to 22.

20. The quantum dot electroluminescent device according to claim 16, wherein the carboxylic acid is selected from fatty acids having a carbon chain length of 8 to 22.
